(19) United States
(12) Patent Application Publication
(10) Pub. No.: US 2026/0082985 A1
(43) Pub. Date: Mar. 19, 2026

(54) SEMICONDUCTOR DEVICE AND METHOD FOR MANUFACTURING THE SEMICONDUCTOR DEVICE

(71) Applicants: Kabushiki Kaisha Toshiba, Tokyo (JP); Toshiba Electronic Devices & Storage Corporation, Tokyo (JP)

(72) Inventor: Yoshiharu TAKADA, Nonoichi Ishikawa (JP)

(21) Appl. No.: 19/067,785

(22) Filed: Feb. 28, 2025

(30) Foreign Application Priority Data
Sep. 19, 2024 (JP) 2024-162667

(51) Int. Cl. H01L 23/31; H01L 21/304; H01L 21/56; H10D 30/66

(52) U.S. Cl. CPC H10W 74/134; H10P 52/00; H10W 74/01; H10D 30/668

(57) ABSTRACT

A semiconductor device comprising: an upper surface; a lower surface opposite to the upper surface; a first side surface; a second side surface contiguous with the upper surface and having irregularities; a step surface connecting the first side surface and the second side surface and facing upward; and a protective film covering at least a part of the upper surface, the entire second side surface, and at least a part of the step surface.

### CROSS-REFERENCE TO RELATED APPLICATIONS

This application is based upon and claims the benefit of priority from Japanese Patent Application No. 2024-162667, filed on September 19, 2024, the entire contents of which are incorporated herein by reference.

### FIELD

Embodiments described herein relate generally to a semiconductor device and method for manufacturing the semiconductor device.

### BACKGROUND

In semiconductor devices, such as MOSFETs (metal-oxide-semiconductor field effect transistors), a protective film may be provided to cover the surface of the semiconductor substrate. In such semiconductor devices, it is desirable to improve reliability.

### BRIEF DESCRIPTION OF THE DRAWINGS

FIG. 1 is a schematic cross-sectional view illustrating a semiconductor device according to the embodiment.

FIG. 2A is a schematic plan view illustrating a semiconductor layer, and FIG. 2B is a schematic side view illustrating the semiconductor layer.

FIGS. 3A, 3B, 4A, 4B, 5A, 5B, 6A, and 6B are schematic cross-sectional views illustrating a manufacturing method of the semiconductor device according to the embodiment.

FIG. 7 is a schematic cross-sectional view illustrating a semiconductor device according to a reference example.

FIG. 8 is a schematic cross-sectional view illustrating an example of a gate structure provided in the semiconductor layer.

### DETAILED DESCRIPTION

A semiconductor device according to an embodiment includes: an upper surface; a lower surface opposite to the upper surface; a first side surface; a second side surface contiguous with the upper surface and having irregularities; a step surface connecting the first side surface and the second side surface and facing upward; and a protective film covering at least a part of the upper surface, the entire second side surface, and at least a part of the step surface.

The embodiments of the present invention will be described below with reference to the drawings. The drawings are schematic or conceptual, and the relationships between the thickness and width of each part, the size ratios between parts, etc., are not necessarily the same as actual ones. Even if the same part is depicted in different figures, the dimensions and ratios may differ in the different figures. In this specification and the drawings, elements that have already been described are denoted by the same reference numerals, and detailed descriptions are appropriately omitted. In the following description and drawings, the notations n+ and n- indicate the relative impurity concentrations. That is, the notation with "+" indicates a relatively higher impurity concentration than the notation without "+" or "-", and the notation with "-" indicates a relatively lower impurity concentration than the notation without "+" or "-". These notations represent the relative impurity concentration after compensation when both p type and n type impurities are included in each region. In the following examples, the first conductivity type is n type, and the second conductivity type is p type. However, in the embodiments described below, the p type and n type of each semiconductor region may be reversed.

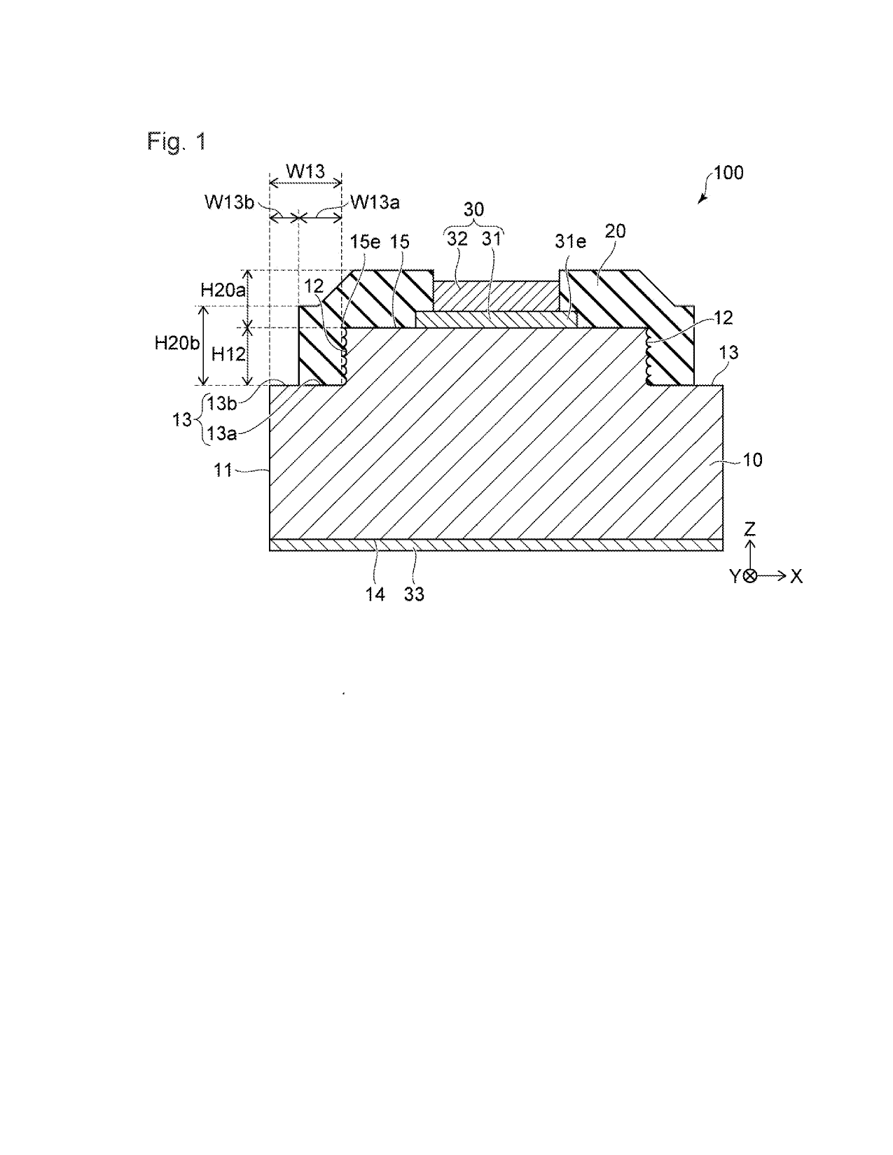

FIG. 1 is a schematic cross-sectional view illustrating a semiconductor device according to the embodiment. As shown in FIG. 1, the semiconductor device 100 according to the embodiment includes a semiconductor layer 10, a protective film 20, a first electrode 30, and a second electrode 33. The semiconductor device 100 is, for example, a semiconductor chip including a vertical MOSFET.

The semiconductor layer 10 is a semiconductor substrate (e.g., an Si substrate) including a semiconductor such as silicon (Si). The semiconductor layer 10 has a lower surface 14 and an upper surface 15 opposite to the lower surface 14. The upper surface 15 is a device surface where elements such as transistors are provided. Specifically, a gate structure is formed on the upper surface 15 side. The protective film 20 is provided on the upper surface side of the semiconductor layer 10.

In the description of the embodiment, the X, Y, and Z directions, which are orthogonal to each other, are used. The direction from the semiconductor layer 10 to the protective film 20 is along the Z direction. The upper surface 15 and the lower surface 14 extend along the X-Y plane. The planar shape of the semiconductor device 100 viewed from above is, for example, rectangular, and each side of the rectangle extends along the X direction or the Y direction. For convenience, the direction from the semiconductor layer 10 to the protective film 20 is referred to as "up," and the opposite direction is referred to as "down." These directions are based on the relative positional relationship between the semiconductor layer 10 and the protective film 20 and are independent of the direction of gravity.

The semiconductor layer 10 has a side surface connecting the upper surface 15 and the lower surface 14. A recess is formed on the side of the upper surface 15 of this side surface. That is, the semiconductor layer 10 has a first side surface 11 and a second side surface 12. The first side surface 11 and the second side surface 12 are surfaces facing the outside of the semiconductor device. The second side surface 12 is located on the side of the upper surface 15 relative to the first side surface 11. The second side surface 12 extends downward from the outer edge of the upper surface 15. The second side surface 12 is a recessed region on the side surface of the semiconductor layer 10 relative to the first side surface 11. The second side surface 12 has irregularities. The first side surface 11 does not have irregularities like the second side surface 12. The first side surface 11 is flatter than the second side surface 12. The irregularities of the second side surface 12 are more significant compared to minor irregularities that occur as noise due to processing errors. For example, the irregularities of the second side surface 12 are more significant than surface roughness due to slight recesses or protrusions arranged at random intervals or directions. The irregularities of the second side surface 12 may have a regular pattern and may have recesses or protrusions arranged in a certain direction.

The semiconductor layer 10 further has a surface (referred to as a step surface 13) connecting the first side surface 11 and the second side surface 12 and facing upward. The step surface 13 extends from the upper end of the first side surface 11 to the lower end of the second side surface 12. The step surface 13 extends along the X-Y plane. A step is formed between the step surface 13 and the upper surface 15 by the second side surface 12. The step surface 13 does not have irregularities like the second side surface 12. The step surface 13 is thus flatter than the second side surface 12.

The protective film 20 is, for example, a water-repellent insulating film. The protective film 20 can be made of a resin such as polyimide. The protective film 20 covers at least a part of the upper surface 15, at least a part of the second side surface 12, and at least a part of the step surface 13. The protective film 20 is a film formed integrally and continuously contacts at least a part of the upper surface 15, at least a part of the second side surface 12, and at least a part of the step surface 13.

More specifically, the protective film 20 contacts a region including at least the outer peripheral edge 15e of the upper surface 15. The protective film 20 contacts the entire second side surface 12. The surface (side surface) of the protective film 20 does not need to match the irregularities of the second side surface 12. The surface (side surface) of the protective film 20 may be flatter than the second side surface 12. The step surface 13 has an inner region 13a covered by and contacting the protective film 20 and an outer region 13b not covered by the protective film 20. The inner region 13a extends outward from the lower end of the second side surface 12. The outer region 13b is located outside the inner region 13a and extends from the outer peripheral end of the inner region 13a to the upper end of the first side surface 11. The first side surface 11 is not covered by or in contact with the protective film 20.

The second electrode 33 is provided below the lower surface 14. The first electrode 30 is provided above the upper surface 15. In this example, the first electrode 30 includes a first conductive layer 31 and a second conductive layer 32 provided on the first conductive layer 31. The protective film 20 covers the end portion 31e (end portion of the first electrode 30) of the first conductive layer 31. That is, the protective film 20 contacts the side surface and the upper surface of the end portion 31e. The protective film 20 covers and contacts the side surface of the second conductive layer 32. The protective film 20 is not provided on the upper surface of the second conductive layer 32. That is, the upper surface of the second conductive layer 32 is exposed upward from an opening provided in the protective film 20.

The first electrode 30 and the second electrode 33 are made of a metal material, for example. For example, the first conductive layer 31 includes aluminum. The second conductive layer 32 includes at least one of nickel and gold. The second electrode 33 includes at least one of nickel, gold, aluminum, and titanium.

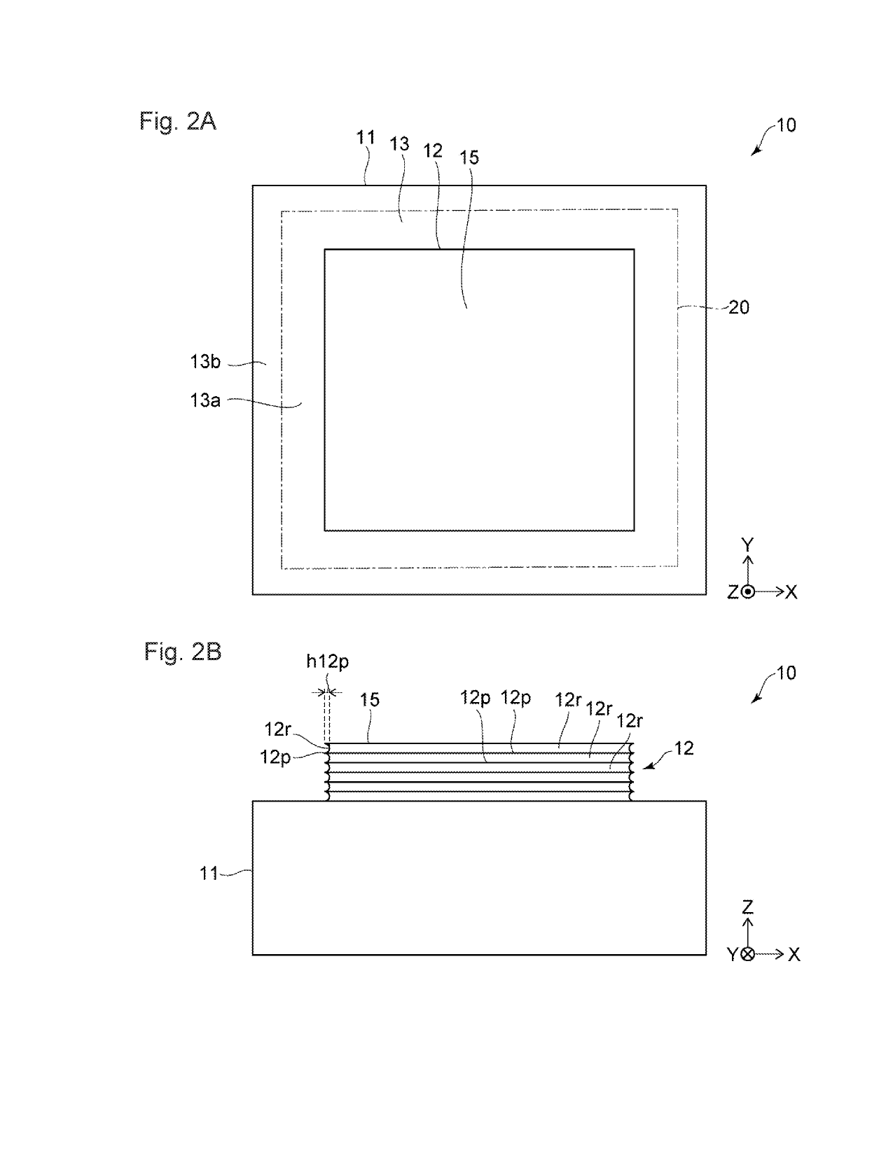

FIG. 2A is a schematic plan view illustrating a semiconductor layer, and FIG. 2B is a schematic side view illustrating the semiconductor layer. As shown in FIG. 2A, the second side surface 12 surrounds the outer periphery of the upper surface 15. The step surface 13 surrounds the outer periphery of the second side surface 12. The first side surface 11 surrounds the outer periphery of the step surface 13. That is, for example, the step on the side surface of the semiconductor layer 10 is provided along the entire outer periphery of the semiconductor layer 10.

In FIG. 2A, the position of the outer periphery of the protective film 20 is indicated by a one-dot chain line. The outer region 13b of the step surface 13 not covered by the protective film 20 surrounds the outer periphery of the inner region 13a of the step surface 13 covered by the protective film 20.

The irregularities of the second side surface 12 are, for example, scallop-shaped. That is, as shown in FIG. 2B, the irregularities of the second side surface 12 include a plurality of recesses 12r arranged in the vertical direction and a plurality of protrusions 12p arranged in the vertical direction. The recesses 12r and the protrusions 12p are alternately arranged in the vertical direction. The recesses 12r are groove-shaped extending along the X direction or the Y direction. The recesses 12r have a curved surface recessed inward. The protrusions 12p have a bent surface pointed outward.

For example, the number of recesses 12r arranged vertically on the second side surface 12 is five or more. The recesses 12r and the protrusions 12p may be periodically (e.g., at a constant period) arranged in the vertical direction. In other words, for example, recesses 12r with a constant vertical length and protrusions 12p with a constant vertical length may be alternately arranged. The height h12p of the irregularities (as depicted in FIG. 2B, the length along the X direction from the bottom of the recess 12r to the top of the protrusion 12p) is, for example, about 1 μm to 3 μm.

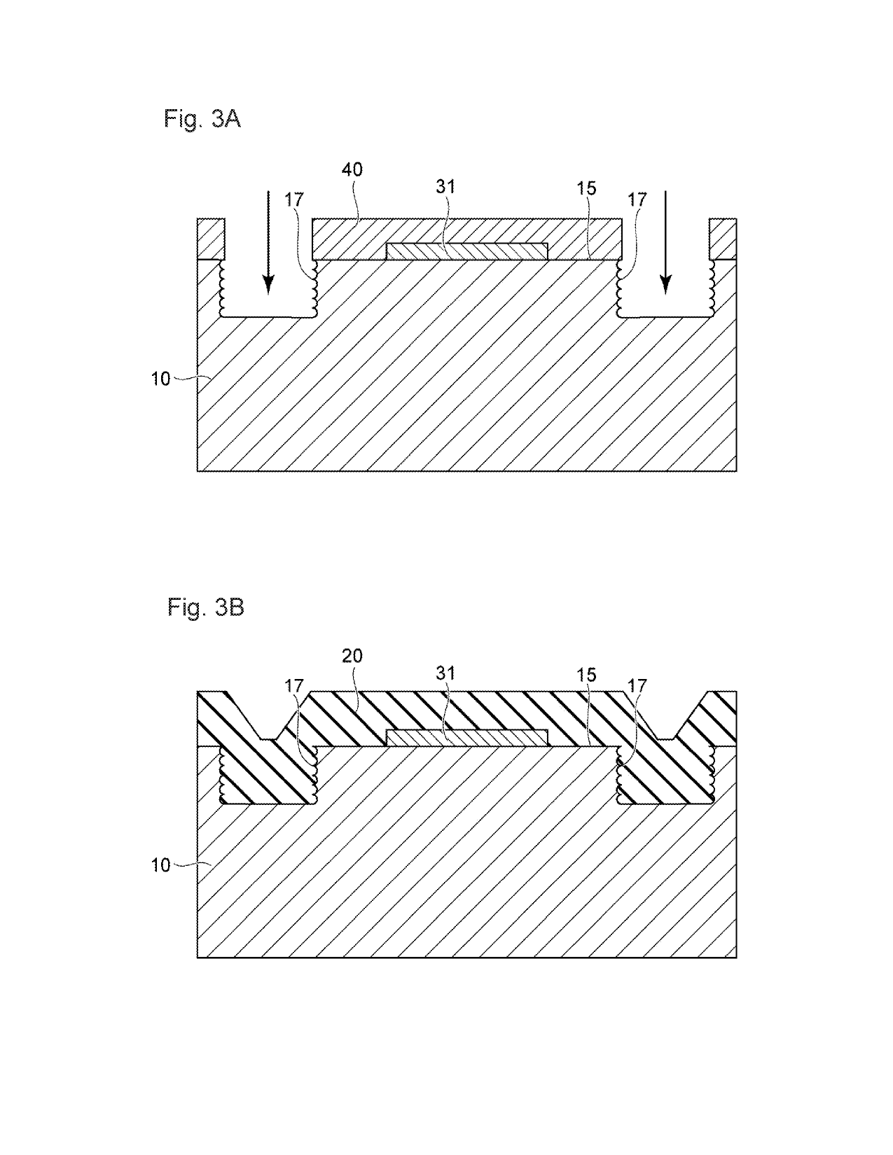

FIGS. 3A to 6B are schematic cross-sectional views illustrating a manufacturing method of the semiconductor device according to the embodiment. As shown in FIG. 3A, a patterned protective film 40 is formed on the upper surface 15 of the semiconductor layer 10. Using the protective film 40 as a mask, a groove 17 is formed on the upper surface 15 by etching. The Bosch process is used for etching.

The Bosch process includes, for example, repeating steps of isotropically etching the semiconductor layer to form a groove, depositing a passivation film on the surface of the semiconductor layer including the groove, and anisotropically etching to remove the passivation film on the bottom surface of the groove. For example, F-based plasma using SF6 gas is used for etching, and CF-based plasma using C4F8 gas is used for the passivation film.

The semiconductor layer 10 is provided in semiconductor elements such as transistors. That is, for example, a gate structure is provided on the upper surface 15 side, and the groove 17 is provided around the region where the gate structure is provided. The first conductive layer 31 is provided above the region where semiconductor elements such as the gate structure are formed.

After removing the protective film 40, a polyimide film is applied on the upper surface 15. Thus, as shown in FIG. 3B, a protective film 20 covering the upper surface 15 of the semiconductor layer 10 and the first conductive layer 31 is formed. A part of the protective film 20 is filled in the groove 17.

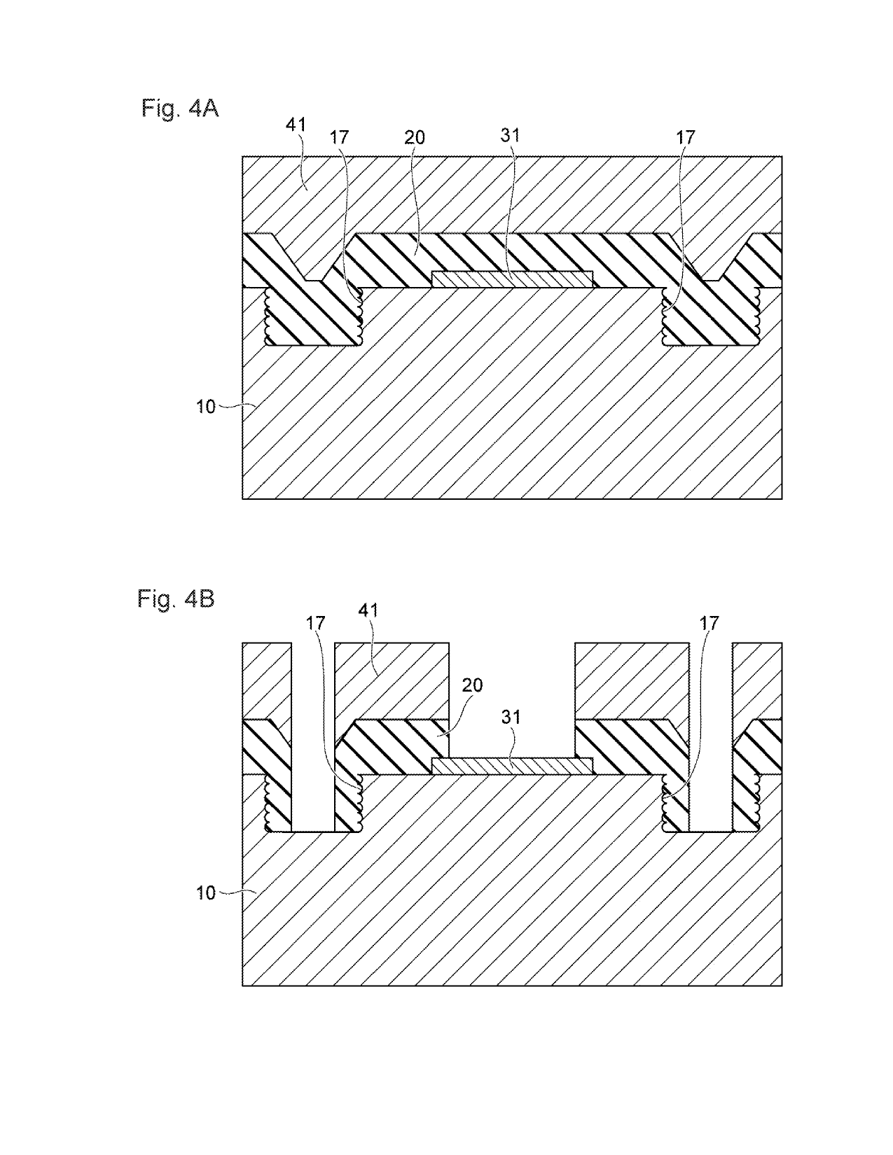

Subsequently, as shown in FIG. 4A, a resist 41 is formed on the protective film 20. Then, as shown in FIG. 4B, the resist 41 is patterned by photolithography. A part of the protective film 20 exposed by the patterning of the resist 41 is dissolved and removed by the developer during the photolithography of the resist 41. As a result, while the side surface of the groove 17 remains covered by the protective film 20, a part of the bottom surface of the groove 17 is exposed through the protective film 20. A part of the upper surface of the first conductive layer 31 is also exposed through the protective film 20.

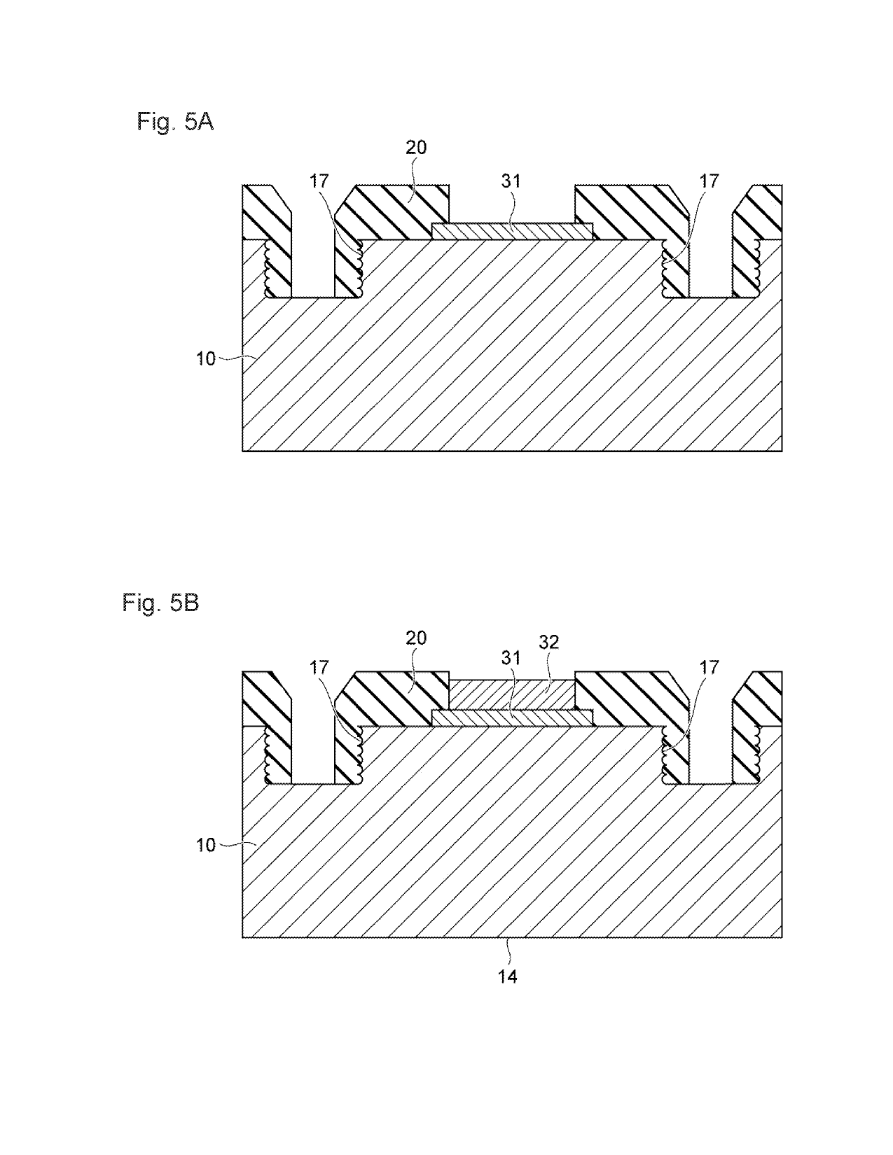

As shown in FIG. 5A, the resist 41 is removed. Then, as shown in FIG. 5B, the second conductive layer 32 is formed on the first conductive layer 31 by, for example, an electroless plating method.

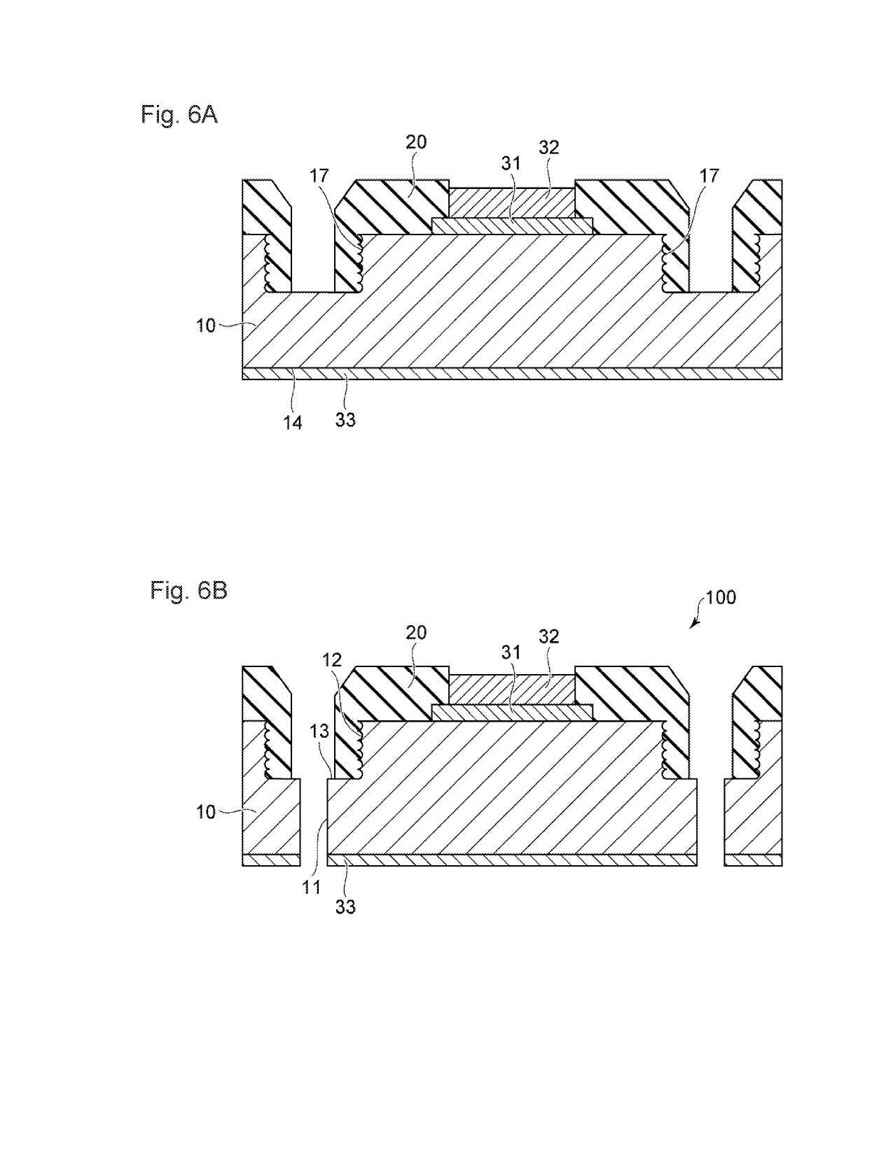

Subsequently, the lower surface side of the semiconductor layer 10 is ground to thin the semiconductor layer 10. Then, as shown in FIG. 6A, the second electrode 33 is formed on the lower surface 14 of the semiconductor layer 10 by, for example, a sputtering method.

Then, as shown in FIG. 6B, the semiconductor layer 10 (and the second electrode 33) is cut at a position where a part of the bottom surface of the groove 17 exposed through the protective film 20, is located. A dicing blade is used for cutting. By this blade dicing process, the semiconductor layer 10 is divided into individual chips. The cut surface of the semiconductor layer 10 becomes the first side surface 11. The side surface of the groove 17 becomes the second side surface 12. The bottom surface of the groove 17 becomes the step surface 13.

For example, when cutting the semiconductor layer 10 by blade dicing, chipping may occur near the cutting position (i.e., the surface edge of the semiconductor layer 10). For example, chipping may occur on the step surface 13. Here, in the embodiment, there is a step (the second side surface 12) between the step surface 13 and the upper surface 15, and the heights of the step surface 13 and the upper surface 15 are different. Therefore, even if chipping occurs on the step surface 13, it can be prevented from extending to the upper surface 15 at the center of the substrate. The range of chipping is limited, and the impact of chipping can be suppressed. Therefore, degradation in characteristics such as reliability as a result of chipping can be prevented.

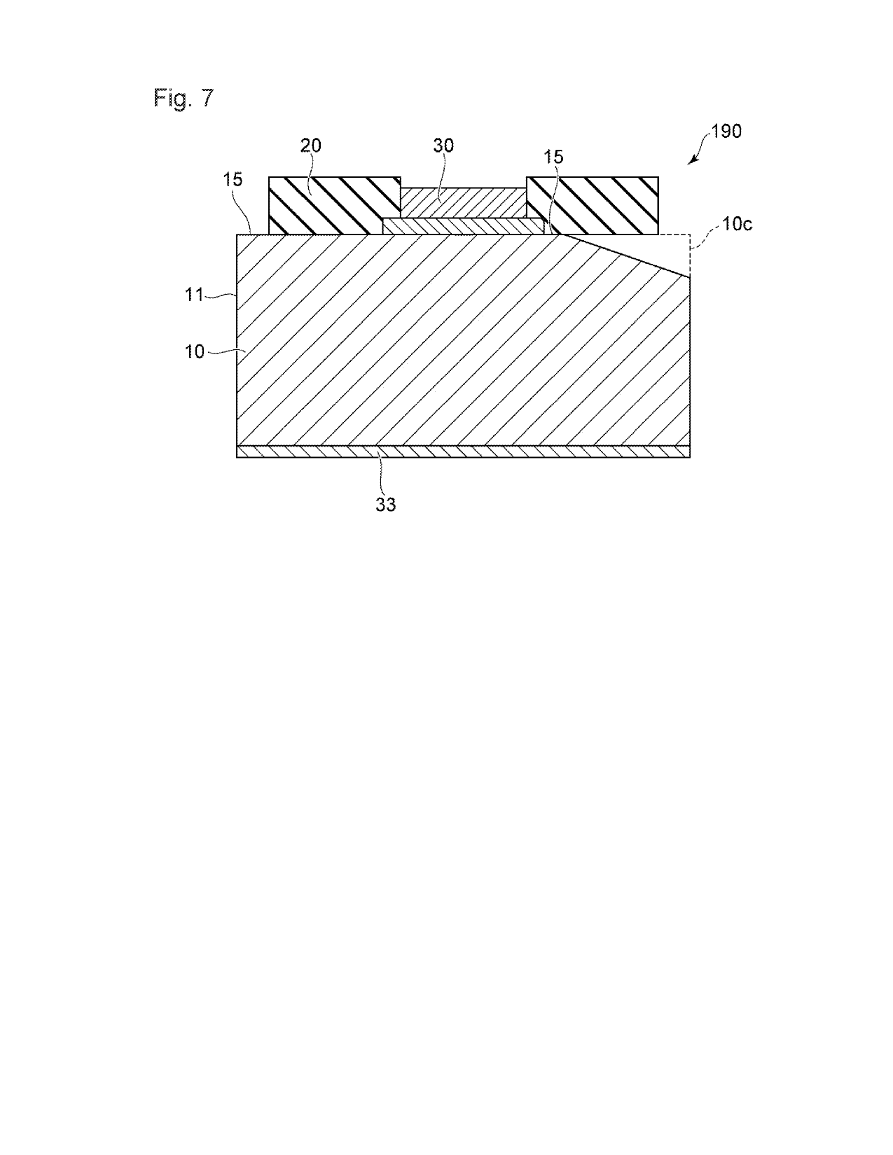

FIG. 7 is a schematic cross-sectional view illustrating a semiconductor device according to a reference example. In the semiconductor device 190 of this reference example, no step is provided on the outer periphery of the upper surface 15 of the semiconductor layer 10. In other words, in the reference example, the step surface 13 and the second side surface 12 are not provided.

For example, devices such as transistor gate structures are formed on the upper surface 15. In the manufacturing of the semiconductor device 190, the cutting position of the semiconductor layer 10 by the dicing blade becomes the edge of the upper surface 15. In this case, as shown in FIG. 7, chipping 10c may occur at the edge of the upper surface 15. The chipping 10c may reach the region where the device on the upper surface 15 is formed, potentially degrading characteristics such as reliability. For example, if chipping 10c occurs, moisture may penetrate from the edge of the semiconductor layer 10 where the chipping occurred, along the path on the surface of the semiconductor layer 10, to the central part of the upper surface 15, thereby reducing reliability. For example, there is a risk that degradation such as dielectric breakdown may occur in a high-humidity environment.

In contrast, in the semiconductor device 100 according to the embodiment, the presence of the second side surface 12 allows the distance from the edge of the semiconductor layer 10 (the edge on the side of the first side surface 11 of the step surface 13) to the upper surface 15 to be increased. Furthermore, the second side surface 12 has irregularities (recesses 12r and protrusions 12p), which further lengthens the moisture penetration path along the surface of the semiconductor layer 10 from the edge of the semiconductor layer 10 to the upper surface 15. This makes it more difficult for moisture to penetrate to the upper surface 15. Therefore, reliability can be improved.

In addition, the irregularities on the second side surface 12 can improve the adhesion between the protective film 20 and the semiconductor layer 10. That is, for example, the adhesion of the protective film 20 to the semiconductor layer 10 can be improved. The protective film 20 becomes less likely to peel off, and reliability can be improved. As a result, moisture penetration can be suppressed.

Alternatively, the height of the step, that is, the length H12 along the vertical direction of the second side surface 12 (shown in FIG. 1), may be greater than the thickness of the protective film 20 (the length H20a along the vertical direction of the portion located above the upper surface 15). By having a longer second side surface 12, the distance between the step surface 13 and the upper surface 15 can be further secured. Also, the length H12 of the second side surface 12 may be greater than the width W13 of the step surface 13. The width W13 corresponds to the shortest distance from the first side surface 11 to the second side surface 12. However, in some embodiments, the length H12 of the second side surface 12 may be equal to or less than the width W13.

For example, the thickness of the protective film 20 (length H20a) is about 3 μm to 10 μm. The length H12 of the second side surface 12 is about 5 μm to 30 μm. The width W13 of the step surface 13 is about 5 μm to 30 μm. Since the step surface 13 is an area where devices such as gate structures are not provided, the width of the step surface 13 may be narrower than the width of the upper surface 15. This allows for effective utilization of the chip area.

The second side surface 12 is formed from the groove 17 described in FIG. 3A and the like. Here, as described above, the groove 17 is formed by the Bosch process. By using the Bosch process, it is easy to deepen the groove 17. That is, it is easy to form a long second side surface 12 in the vertical direction. Furthermore, by using the Bosch process, the irregularities of the second side surface 12 can be formed simultaneously with the formation of the groove 17. In this case, the irregularities have a shape like groove-like recesses 12r arranged in the vertical direction, as described above with respect to FIG. 2B.

As described with respect to FIG. 3B and the like, when forming the protective film 20 on the upper surface 15, the protective film 20 is embedded into the groove 17. This allows the protective film 20 to be formed as a continuous film integrated as one unit. In this case, in the semiconductor device 100 of FIG. 1, the side surface of the protective film 20 becomes thicker. That is, the length H20b of the side surface of the protective film 20 (the length along the vertical direction of the side surface of the protective film 20 located on the step surface 13) is greater than the thickness of the protective film 20 on the upper surface 15 (length H20a).

For example, the length H12 along the vertical direction of the second side surface 12 may be less than half the thickness of the semiconductor layer 10. By not having the length H12 be too long, that is, by not having the groove 17 be too deep, it becomes easier to embed the protective film 20. The thickness of the semiconductor layer 10 is, for example, about 40 μm to 150 μm.

As described with respect to FIGS. 6A and 6B, the exposed bottom surface of the groove 17 is cut by blade dicing. By using blade dicing, the semiconductor layer 10 and the backside metal (second electrode 33) can be cut in the same process. By using blade dicing, the semiconductor layer can be individualized in a simple process while suppressing manufacturing costs. Also, by using blade dicing, it is easy to cut the first side surface 11 flat. The first side surface 11 is flatter than the second side surface 12. When the groove 17 is cut by blade dicing in this way, the step surface 13 forms an inner region 13a covered with the protective film 20 and an outer region 13b not covered with the protective film 20.

Also, for example, as shown in FIG. 1, the width W13a of the inner region 13a of the step surface 13 may be wider than the width W13b of the outer region 13b. By having a wider width W13a of the inner region 13a, moisture penetration to the upper surface 15 can be further suppressed. The width W13a of the inner region 13a corresponds to the shortest distance from the second side surface 12 to the outer region 13b. The width W13b of the outer region 13b corresponds to the shortest distance from the first side surface 11 to the inner region 13a.

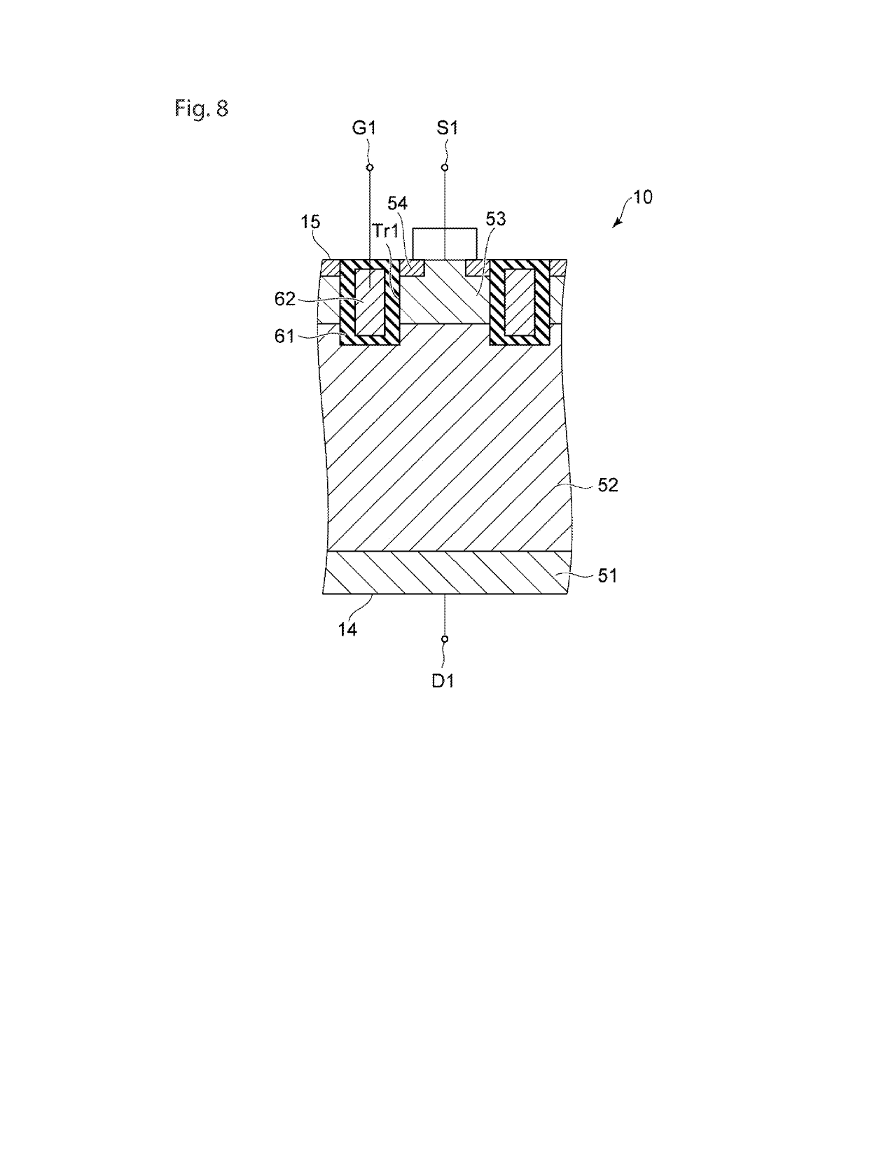

FIG. 8 is a schematic cross-sectional view illustrating an example of a gate structure provided in the semiconductor layer. As shown in FIG. 8, the semiconductor layer 10 includes semiconductor regions 51, 52, 53, and 54. The semiconductor region 51 (drain region) is of the first conductivity type (n+ type) and forms the lower surface 14 of the semiconductor layer 10. The semiconductor region 52 (drift region) is provided on the semiconductor region 51 and is of the first conductivity type (n- type). The semiconductor region 53 (base region) is provided on part of the semiconductor region 52 and is of the second conductivity type. The semiconductor region 54 (source region) is provided on part of the semiconductor region 53 and is of the first conductivity type (n+ type). The semiconductor regions 53 and 54 form the upper surface 15 of the semiconductor layer 10.

A transistor gate structure is provided on the upper surface 15. The gate structure includes a gate insulating film 61 and a gate conductive portion 62. The gate insulating film 61 is, for example, in contact with the upper surface 15 of the semiconductor layer 10. In this example, a trench Tr1 is formed in the upper surface 15, and the gate insulating film 61 and the gate conductive portion 62 are arranged in the trench Tr1. The gate insulating film 61 is provided to be in contact with the side surface of the trench Tr1. The gate conductive portion 62 faces the semiconductor regions 52, 53, and 54 via the gate insulating film 61.

The gate conductive portion 62 is electrically connected to a gate electrode G1 provided above the upper surface 15. The semiconductor regions 53 and 54 are electrically connected to a source electrode S1 provided above the upper surface 15. The semiconductor region 51 is electrically connected to a drain electrode D1 provided below the lower surface 14. The first electrode 30 described above in FIG. 1 corresponds to the source electrode S1 (or the gate electrode G1), and the second electrode 33 corresponds to the drain electrode D1.

The gate structure controls the current flowing between the drain electrode D1 and the source electrode S1 through the semiconductor layer 10. That is, for example, while applying a positive voltage to the drain electrode D1 relative to the source electrode S1, the voltage of the gate conductive portion 62 is controlled via the gate electrode G1. When the voltage of the gate conductive portion 62 exceeds the threshold, an on-current flows between the drain electrode D1 and the source electrode S1. When the voltage of the gate conductive portion 62 is below the threshold, no on-current flows.

Note that in FIG. 8, a trench-type vertical MOSFET is illustrated, but the embodiment is not limited to this and may be, for example, a planar type.

According to the embodiment, a semiconductor device and a manufacturing method thereof that can improve reliability can be provided.

In this specification, "electrically connected" includes not only cases where they are directly connected in contact but also cases where they are connected via other conductive members.

While several embodiments of the present invention have been illustrated, these embodiments are presented as examples and are not intended to limit the scope of the invention. These novel embodiments can be implemented in various other forms, and various omissions, substitutions, and changes can be made without departing from the spirit of the invention. These embodiments and their modifications are included in the scope and spirit of the invention and are included in the invention described in the claims and their equivalents. Furthermore, the above-described embodiments can be implemented in combination with each other.

What is claimed is:

1. A semiconductor device comprising:
an upper surface;
a lower surface opposite to the upper surface;
a first side surface;
a second side surface contiguous with the upper surface and having irregularities;
a step surface connecting the first side surface and the second side surface and facing upward; and
a protective film covering at least a part of the upper surface, the entire second side surface, and at least a part of the step surface.

2. The semiconductor device according to claim 1, wherein
a height of the side surface of the protective film positioned on the step surface is greater than a thickness of the portion of the protective film positioned above the upper surface.

3. The semiconductor device according to claim 1, wherein
the irregularities of the second side surface include a plurality of recesses arranged in a vertical direction, and the recesses are groove-shaped and extend in a direction perpendicular to the vertical direction.

4. The semiconductor device according to claim 1, wherein
the step surface includes an inner region covered by the protective film and an outer region positioned outside the inner region and not covered by the protective film.

5. The semiconductor device according to claim 4, wherein a width of the inner region is greater than a width of the outer region.

6. The semiconductor device according to claim 1, wherein a height of the second side surface is greater than a thickness of a portion of the protective film positioned above the upper surface.

7. The semiconductor device according to claim 1, wherein a height of the second side surface is greater than a width of the step surface.

8. The semiconductor device according to claim 1, further comprising a first electrode provided on the upper surface, wherein the protective film covers an end portion of the first electrode, and a part of the first electrode is not covered by the protective film.

9. The semiconductor device according to claim 8, further comprising a second electrode provided on the first electrode, wherein the protective film covers a side surface of the second electrode and does not cover an upper surface of the second electrode.

10. The semiconductor device according to claim 9, further comprising a third electrode provided on the lower surface.

11. The semiconductor device according to claim 1, wherein the first side surface is smoother than the second side surface.

12. A method for manufacturing a semiconductor device, comprising:
forming a groove by etching an upper surface of a semiconductor layer of the semiconductor device using a Bosch process;
forming a protective film covering a side surface of the semiconductor layer formed by the groove and the upper surface of the semiconductor layer;
removing a part of the protective film inside the groove to expose a part of the semiconductor layer though a bottom portion of the groove while keeping the side surface of the semiconductor layer covered by the protective film; and
cutting the semiconductor layer at the position of the part of the semiconductor layer exposed though the bottom portion of the groove.

13. The method of claim 12, wherein
the semiconductor device includes a first electrode formed on the upper surface of the semiconductor layer and the groove is formed at a location on the upper surface that is spaced apart from the first electrode, and
the protective film is formed to cover the first electrode.

14. The method of claim 13, further comprising:
removing a part of the protective film above the first electrode; and
forming a second electrode on the first electrode.

15. The method of claim 14, further comprising:
grinding a lower surface of the semiconductor layer to thin the semiconductor layer; and
forming a third electrode on the lower surface of the semiconductor layer.

16. The method of claim 15, wherein the semiconductor layer includes:
a first semiconductor region of a first conductivity type on the third electrode;
a second semiconductor region of a second conductivity type on the first semiconductor region, a part of the second semiconductor region being exposed on the upper surface of the semiconductor layer; and
a third semiconductor region of the first conductivity type on the second semiconductor region, a part of the third semiconductor region being exposed on the upper surface of the semiconductor layer.

17. The method of claim 12, wherein
the cutting forms a second side surface of the semiconductor layer that is connected to the side surface formed by the groove by a step surface having an inner region covered by the protective film and an outer region positioned outside the inner region and not covered by the protective film.

18. The method of claim 17, wherein the width of the inner region is wider than the width of the outer region.

19. The method of claim 18, wherein a height of the side surface formed by the groove is greater than a width of the step surface.

20. The method of claim 17, wherein the second side surface is smoother than the side surface formed by the groove.
